(19) United States
(12) Patent Application Publication
(10) Pub. No.: US 2008/0237719 A1
(43) Pub. Date: Oct. 2, 2008

(54) Multi-gate structure and method of doping same

(76) Inventors: Brian S. Doyle, Portland, OR (US); Suman Datta, Beaverton, OR (US); Jack T. Kavalieros, Portland, OR (US); Rafael Rios, Portland, OR (US)

Correspondence Address: INTEL CORPORATION;c/o INTELLEVATE, LLC, P.O. BOX 52050, MINNEAPOLIS, MN, 55402, US

(21) Appl. No.: 11/729,198

(22) Filed: Mar. 28, 2007

(51) Int. Cl. H01L 27/12; H01L 21/8238

(52) U.S. Cl. 257/351; 438/154; 257/E21.632; 257/E27.112

(57) ABSTRACT

A multi-gate structure includes a substrate (110, 210, 410), an electrically insulating layer (120, 220, 420) over the substrate, and a first semiconducting fin (130, 230, 430) above the electrically insulating layer. The first semiconducting fin includes a top region (131, 231, 431), a first side region (132, 232, 432), and a second side region (133, 233, 433). The top region, the first side region, and the second side region have doping concentrations that are substantially equal to each other. The multi-gate structure may be made by depositing a solid source material (510) over the semiconducting fin, and by annealing the multi-gate structure such that dopants from the solid source material diffuse into the semiconducting fin and uniformly dope the top region and the first and second side regions.

### FIELD OF THE INVENTION

The disclosed embodiments of the invention relate generally to three-dimensional multi-gate structures, and relate more particularly to the doping of three-dimensional multi-gate structures.

### BACKGROUND OF THE INVENTION

Three-dimensional multi-gate structures, including tri-gate transistors and the like, offer performance and efficiency improvements over alternative technologies that make them ideally suited to act as building blocks for upcoming microprocessor generations. Existing implant techniques, however, are not able to adequately dope the fins that are characteristic features of the 3-D multi-gate structure. A vertical implant only dopes the top of the fins. An implant angled at 45 degrees dopes the top of the fins with twice the dose as the sides. Using a 60 degree angled implant ensures that the top and sidewalls are equally doped, but at a cost of unequal doping depths; the sidewalls get implanted deeper than the top leading to effective length (L_{eff}) differences after anneal. Furthermore, as the fin pitch decreases, one fin shields the bottoms of adjacent fins from the doping implants. Accordingly, there exists a need for a way to produce a 3-D multi-gate structure in which the top and the sides of the fin are uniformly doped.

### BRIEF DESCRIPTION OF THE DRAWINGS

The disclosed embodiments will be better understood from a reading of the following detailed description, taken in conjunction with the accompanying figures in the drawings in which:

FIG. 1 is a schematic perspective view of a portion of a multi-gate structure according to an embodiment of the invention;

FIG. 2 is a schematic perspective view of a portion of a different multi-gate structure according to an embodiment of the invention;

FIG. 3 is a flowchart illustrating a method of doping a multi-gate structure according to an embodiment of the invention; and

FIGS. 4-6 are schematic perspective views of portions of a different multi-gate structure at various points in its manufacturing process according to an embodiment of the invention.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. The same reference numerals in different figures denote the same elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method. Furthermore, the terms “comprise,” “include,” “have,” and any variations thereof, are intended to cover a non-exclusive inclusion, such that a process, method, article, or apparatus that comprises a list of elements is not necessarily limited to those elements, but may include other elements not expressly listed or inherent to such process, method, article, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “in one embodiment” herein do not necessarily all refer to the same embodiment.

### DETAILED DESCRIPTION OF THE DRAWINGS

In one embodiment of the invention, a multi-gate structure comprises a substrate, an electrically insulating layer over the substrate, and a first semiconducting fin above the electrically insulating layer. The first semiconducting fin comprises a top region, a first side region, and a second side region opposite the first side region. The top region has a first doping concentration, the first side region has a second doping concentration, and the second side region has a third doping concentration. The first doping concentration is substantially equal to the second doping concentration and to the third doping concentration. In an embodiment, the multi-gate structure may be made by depositing a solid source material over the semiconducting fin such that the solid source material covers at least portions of the top, the first side, and the second side, and by annealing the multi-gate structure such that dopants from the solid source material diffuse into the semiconducting fin and uniformly dope the top, the first side, and the second side.

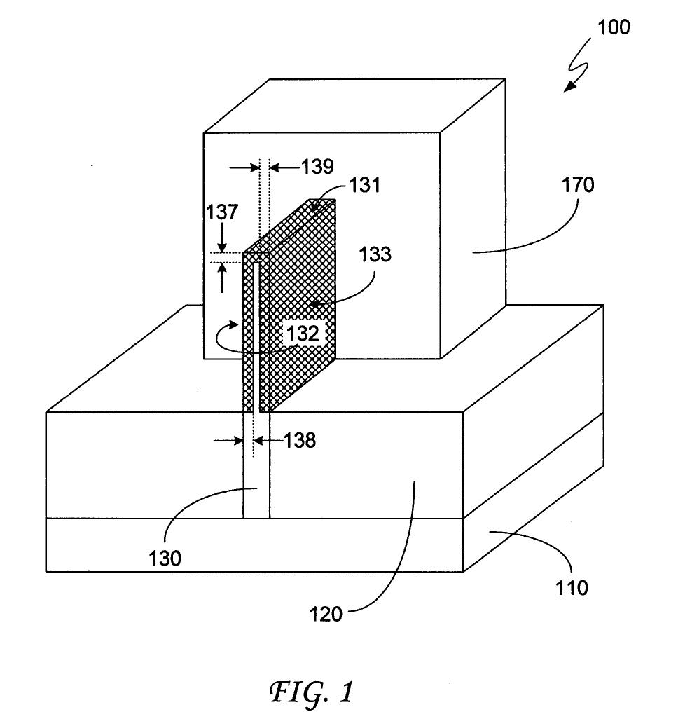

Referring now to the drawings, FIG. 1 is a schematic perspective view of a portion of a multi-gate structure 100 according to an embodiment of the invention. As illustrated in FIG. 1, multi-gate structure 100 comprises a substrate 110, an electrically insulating layer 120 (such as an oxide layer or a nitride layer or the like) over substrate 110, a semiconducting fin 130 above electrically insulating layer 120, and a polysilicon region 170 straddling semiconducting fin 130 above electrically insulating layer 120.

Semiconducting fin 130 comprises a top region 131 with a first doping concentration, a side region 132 with a second doping concentration, and a side region 133 with a third doping concentration opposite side region 132. The first doping concentration is substantially equal to the second doping concentration and to the third doping concentration.

In one embodiment, top region 131 has a depth 137, side region 132 has a depth 138, and side region 133 has a depth 139. As illustrated, depths 137, 138, and 139 are the depths (into the interior of semiconducting fin 130) to which the doping implant extends, as measured from the respective surfaces of top region 131, side region 132, and side region 133. In the illustrated embodiment, the first depth is substantially equal to the second depth and to the third depth.

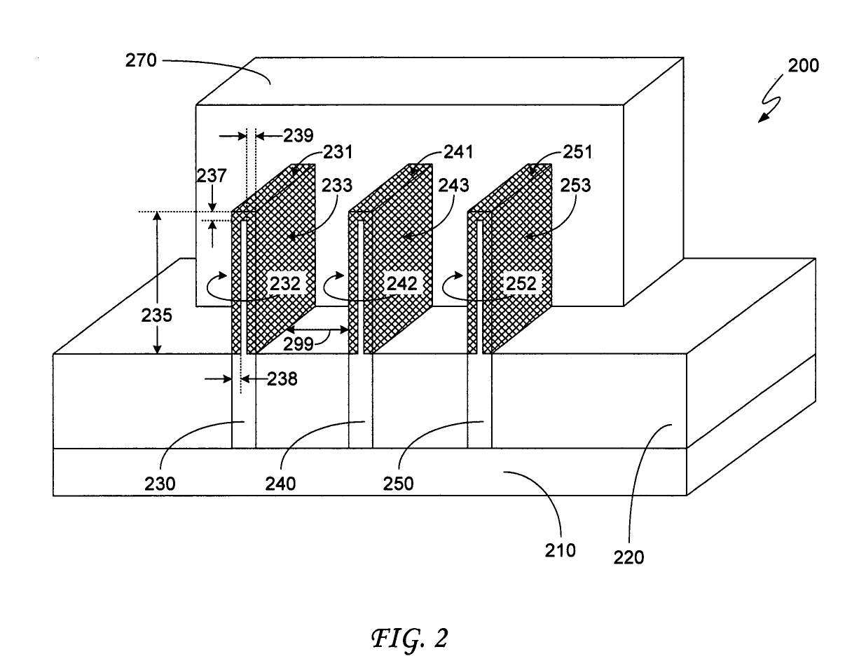

FIG. 2 is a schematic perspective view of a portion of a multi-gate structure 200 according to an embodiment of the invention. As illustrated in FIG. 2, multi-gate structure 200 comprises a substrate 210, an electrically insulating layer 220 over substrate 210, a semiconducting fin 230 above electrically insulating layer 220, and a polysilicon region 270 straddling semiconducting fin 230 above electrically insulating layer 220. As an example, substrate 210, electrically insulating layer 220, semiconducting fin 230, and polysilicon region 270 can be similar to, respectively, substrate 110, electrically insulating layer 120, semiconducting fin 130, and polysilicon region 170, all of which are shown in FIG. 1.

Multi-gate structure 200 further comprises, in contrast to multi-gate structure 100 of FIG. 1, a semiconducting fin 240 and a semiconducting fin 250, both of which are, like semiconducting fin 230, above electrically insulating layer 220. Multi-gate structure 200 thus comprises a plurality of semiconducting fins, including at least semiconducting fins 230, 240, and 250 and possibly including additional semiconducting fins that are not depicted in FIG. 2. Polysilicon region 270 straddles semiconducting fins 240 and 250 in the same way in which it straddles semiconducting fin 230.

Being similar to semiconducting fin 130 of FIG. 1, semiconducting fin 230 comprises a top region 231 with a fourth doping concentration, a side region 232 with a fifth doping concentration, and a side region 233 with a sixth doping concentration opposite side region 232, where the fourth, fifth, and sixth doping concentrations are substantially equal to each other. Furthermore, in one embodiment top region 231 has a depth 237, side region 232 has a depth 238, and side region 233 has a depth 239, where depths 237, 238, and 239 are substantially equal to each other. As with depths 137, 138, and 139, depths 237, 238, and 239 are the depths (into the interior of semiconducting fin 130) to which the doping implant extends, as measured from the respective surfaces of top region 231, side region 232, and side region 233.

Semiconducting fin 240 has a top region 241, a side region 242, and a side region 243 opposite side region 242. Similarly, semiconducting fin 250 has a top region 251, a side region 252, and a side region 253 opposite side region 252. The respective doping concentrations of the various regions of semiconducting fins 240 and 250 can be similar to corresponding regions of semiconducting fin 230. Furthermore, although they are not explicitly illustrated in FIG. 2, the implant depths of the various regions of semiconducting fins 240 and 250 can be similar to the implant depths of corresponding regions of semiconducting fin 230. Accordingly, in at least one embodiment of multi-gate structure 200, the doping concentrations and the implant depths for each one of the plurality of semiconducting fins are substantially equal across each of the three mentioned fin regions.

In one embodiment, adjacent ones of the plurality of semiconducting fins have a separation distance (this is often called “pitch”) that is less than a greatest height of the adjacent ones of the plurality of semiconducting fins. For example, in the illustrated embodiment, semiconducting fin 230 has a height 235, and the heights of semiconducting fins 240 and 250 are substantially equal to height 235. Meanwhile, the pitch of the semiconducting fins is equal to a separation distance 299, which, as illustrated, has a magnitude that is less than height 235.

As an example, one (or more than one) of the plurality of semiconducting fins can be an NMOS structure while a different one (or more than one) of the plurality of semiconducting fins can be a PMOS structure. The NMOS and PMOS structures can be arranged in alternating order or in any other order.

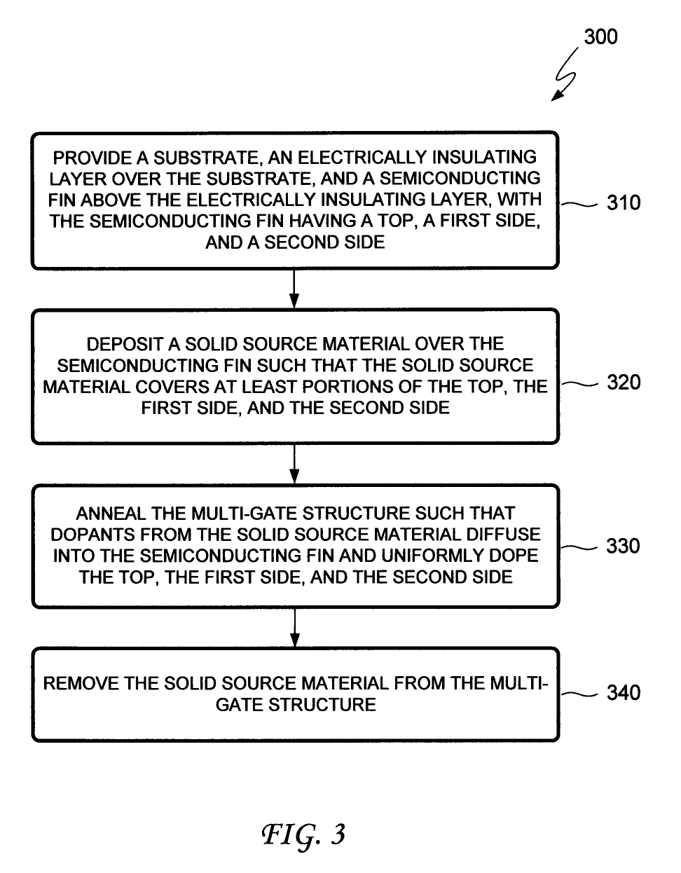

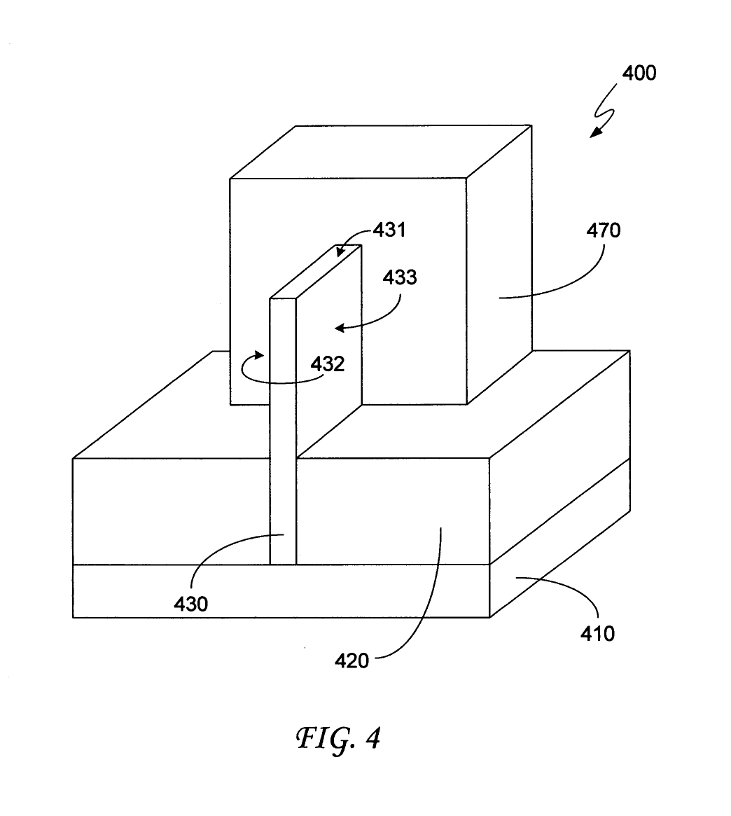

FIG. 3 is a flowchart illustrating a method 300 of doping a multi-gate structure according to an embodiment of the invention. A step 310 of method 300 is to provide a substrate, an electrically insulating layer over the substrate, and a semiconducting fin above the electrically insulating layer, with the semiconducting fin having a top, a first side, and a second side. As an example, the substrate, the electrically insulating layer, and the semiconducting fin can be similar to, respectively, substrate 110, electrically insulating layer 120, and semiconducting fin 130, all of which are shown in FIG. 1. As another example, the substrate, the electrically insulating layer, and the semiconducting fin can be similar to, respectively, a substrate 410, an electrically insulating layer 420, and a semiconducting fin 430, all of which are first shown in FIG. 4. Specifically, semiconducting fin 430, in the illustrated embodiment, comprises a top region 431, a side region 432, and a side region 433 opposite side region 432.

FIG. 4 is a schematic perspective view of a portion of a multi-gate structure 400 at a particular point in its manufacturing process according to an embodiment of the invention. As illustrated in FIG. 4, and as mentioned above, multi-gate structure 400 comprises substrate 410, electrically insulating layer 420, and semiconducting fin 430. As an example, and as implied above, substrate 410, electrically insulating layer 420, and semiconducting fin 430 can be similar to, respectively, substrate 110, electrically insulating layer 120, and semiconducting fin 130 that are shown in FIG. 1. Multi-gate structure 400 further comprises a polysilicon region 470. As an example, polysilicon region 470 can be similar to polysilicon region 170 that is shown in FIG. 1. It should be noted that although FIG. 4 and subsequent figures depicting multi-gate structure 400 show only a single semiconducting fin, multi-gate structure 400 can, in at least some (non-illustrated) embodiments comprise a plurality of semiconducting fins that includes the single semiconducting fin that is shown.

In one embodiment, step 310 comprises providing a plurality of semiconducting fins that includes the semiconducting fin mentioned above in the initial description of the given embodiment of step 310. In that embodiment, method 300 can further comprise spacing adjacent ones of the plurality of semiconducting fins such that they are separated from each other by a distance that is no greater than a greatest height of the adjacent ones of the plurality of semiconducting fins. Accordingly, in that embodiment the multi-gate structure can be similar to multi-gate structure 200 that is shown in FIG. 2.

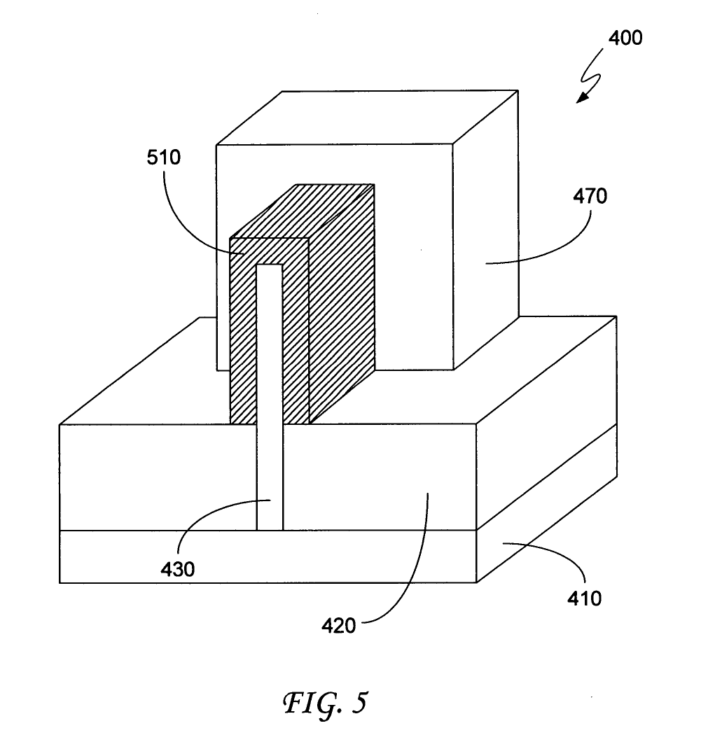

A step 320 of method 300 is to deposit a solid source material over the semiconducting fin such that the solid source material covers at least portions of the top, the first side, and the second side. As an example, the solid source material can be similar to a solid source material 510 that is first shown in FIG. 5.

FIG. 5 is a schematic perspective view of a portion of multi-gate structure 400 at a particular point in its manufacturing process according to an embodiment of the invention. As illustrated in FIG. 5, and as mentioned above, multi-gate structure 400 further comprises solid source material 510. In the illustrated embodiment, solid source material 510 is conformally deposited over top region 431, and side regions 432 and 433 (see FIG. 4) to a substantially uniform thickness on all three exposed sides of semiconducting fin 430.

In one embodiment, step 310 comprises providing a PMOS semiconducting fin. In that embodiment, step 320 may comprise depositing a borosilicate glass or the like as the solid source material. In one embodiment, step 310 comprises providing an NMOS semiconducting fin. In that embodiment, step 320 may comprise depositing a phosphosilicate glass or the like as the solid source material. In an embodiment where step 310 or another step comprises providing the multi-gate structure with a plurality of semiconducting fins, and where at least one of those semiconducting fins is a PMOS semiconducting fin, step 320 can again comprise depositing a borosilicate glass or the like as the solid source material. Similarly, in an embodiment where step 310 or another step comprises providing the multi-gate structure with a plurality of semiconducting fins, and where at least one of those semiconducting fins is an NMOS semiconducting fin, step 320 can again comprise depositing a phosphosilicate glass or the like as the solid source material. Furthermore, in an embodiment where step 310 or another step comprises providing the multi-gate structure with a plurality of semiconducting fins, and where at least one of those semiconducting fins is a PMOS semiconducting fin and at least another one of those semiconducting fins is an NMOS semiconducting fin, step 320 can comprise depositing a borosilicate glass or the like over the PMOS semiconducting fin as a solid source material and depositing a phosphosilicate glass or the like over the NMOS semiconducting fin as a solid source material.

A step 330 of method 300 is to anneal the multi-gate structure such that dopants from the solid source material diffuse into the semiconducting fin and uniformly dope the top, the first side, and the second side. Step 330 thus results in a multi-gate structure having equal dopant concentrations on each of the top, first side, and second side as is the case, for example, for multi-gate structures 100 and 200 of FIGS. 1 and 2, respectively. As an example, the anneal may be performed at a temperature of between approximately 950 degrees Celsius and approximately 1050 degrees Celsius for a duration between barely more than zero seconds (for a flash anneal) to approximately ten seconds.

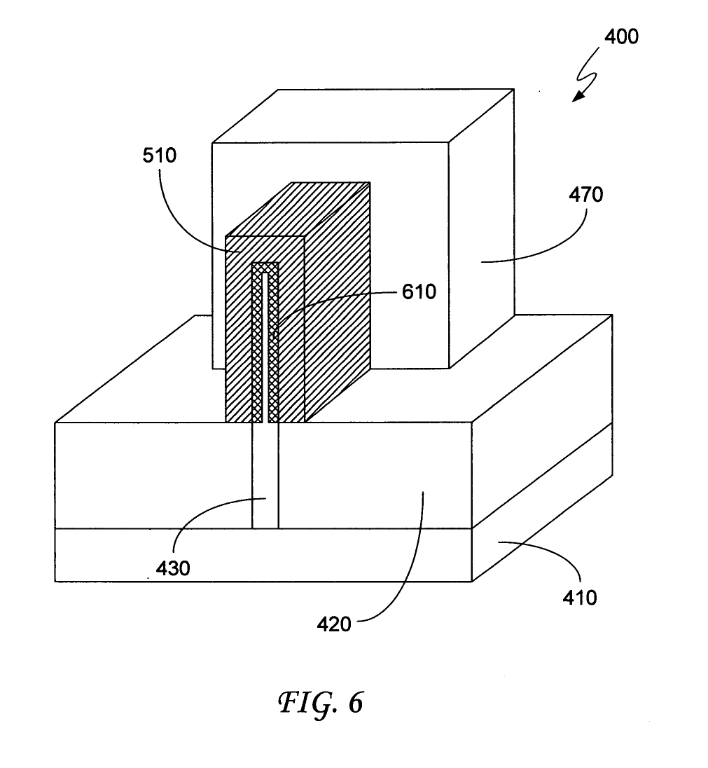

FIG. 6 is a schematic perspective view of a portion of multi-gate structure 400 at a particular point in its manufacturing process according to an embodiment of the invention. As an example, the performance of step 330 may produce a multi-gate structure that has an appearance similar to that of multi-gate structure 400 as it is depicted in FIG. 6. As illustrated there, multi-gate structure 400 further comprises a doped area 610 that is, as mentioned, uniform in concentration and, in at least one embodiment, in depth across all three exposed sides of semiconducting fin 430, i.e., across top region 431, side region 432, and side region 433 (see FIG. 4).

A step 340 of method 300 is to remove the solid source material from the multi-gate structure. As an example, step 340 can comprise etching away the solid source material using a wet etch. Following the performance of step 340 the multi-gate structure may have an appearance similar to the appearance of multi-gate structure 100 of FIG. 1, where semiconducting fin 130 is uniformly doped on both top and sidewalls, i.e., uniformly doped across the top region, the first side region, and the second side region.

Although the invention has been described with reference to specific embodiments, it will be understood by those skilled in the art that various changes may be made without departing from the spirit or scope of the invention. Accordingly, the disclosure of embodiments of the invention is intended to be illustrative of the scope of the invention and is not intended to be limiting. It is intended that the scope of the invention shall be limited only to the extent required by the appended claims. For example, to one of ordinary skill in the art, it will be readily apparent that the multi-gate structures and related methods discussed herein may be implemented in a variety of embodiments, and that the foregoing discussion of certain of these embodiments does not necessarily represent a complete description of all possible embodiments.

Additionally, benefits, other advantages, and solutions to problems have been described with regard to specific embodiments. The benefits, advantages, solutions to problems, and any element or elements that may cause any benefit, advantage, or solution to occur or become more pronounced, however, are not to be construed as critical, required, or essential features or elements of any or all of the claims.

Moreover, embodiments and limitations disclosed herein are not dedicated to the public under the doctrine of dedication if the embodiments and/or limitations: (1) are not expressly claimed in the claims; and (2) are or are potentially equivalents of express elements and/or limitations in the claims under the doctrine of equivalents.

What is claimed is:

1. A multi-gate structure comprising:
a substrate;
an electrically insulating layer over the substrate; and
a first semiconducting fin above the electrically insulating layer,
wherein:
the first semiconducting fin comprises a top region, a first side region, and a second side region opposite the first side region;
the top region has a first doping concentration, the first side region has a second doping concentration, and the second side region has a third doping concentration; and
the first doping concentration is substantially equal to the second doping concentration and to the third doping concentration.

2. The multi-gate structure of claim 1 wherein:
the top region has a first depth, the first side region has a second depth, and the second side region has a third depth; and
the first depth is substantially equal to the second depth and to the third depth.

3. The multi-gate structure of claim 2 wherein:
the multi-gate structure further comprises a plurality of semiconducting fins, including the first semiconducting fin; and
adjacent ones of the plurality of semiconducting fins are spaced apart from each other by a distance that is less than a greatest height of the adjacent ones of the plurality of semiconducting fins.

4. The multi-gate structure of claim 3 wherein:
the first semiconducting fin is an NMOS structure.

5. The multi-gate structure of claim 4 wherein:
the plurality of semiconducting fins comprises a second semiconducting fin; and
the second semiconducting fin is a PMOS structure.

6. A method of doping a multi-gate structure, the method comprising:
providing a substrate, an electrically insulating layer over the substrate, and a semiconducting fin above the electrically insulating layer, the semiconducting fin having a top, a first side, and a second side;
depositing a solid source material over the semiconducting fin such that the solid source material covers at least portions of the top, the first side, and the second side;
annealing the multi-gate structure such that dopants from the solid source material diffuse into the semiconducting fin and uniformly dope the top, the first side, and the second side; and
removing the solid source material from the multi-gate structure.

7. The method of claim 6 wherein:
removing the solid source material comprises etching the solid source material using a wet etch.

8. The method of claim 6 wherein:
providing the semiconducting fin comprises providing a PMOS semiconducting fin; and
depositing the solid source material comprises depositing a borosilicate glass.

9. The method of claim 6 wherein:
providing the semiconducting fin comprises providing an NMOS semiconducting fin; and
depositing the solid source material comprises depositing a phosphosilicate glass.

10. The method of claim 6 wherein:
providing the semiconducting fin comprises providing a plurality of semiconducting fins, including the semiconducting fin; and
the method further comprises spacing adjacent ones of the plurality of semiconducting fins such that they are separated from each other by a distance that is no greater than a greatest height of the adjacent ones of the plurality of semiconducting fins.

11. The method of claim 10 wherein:
providing the plurality of semiconducting fins comprises providing at least one PMOS semiconducting fin; and
depositing the solid source material comprises depositing a borosilicate glass.

12. The method of claim 10 wherein:
providing the plurality of semiconducting fins comprises providing at least one NMOS semiconducting fin; and
depositing the solid source material comprises depositing a phosphosilicate glass.

13. The method of claim 10 wherein:
providing the plurality of semiconducting fins comprises providing at least one PMOS semiconducting fin and at least one NMOS semiconducting fin; and
depositing the solid source material comprises depositing a borosilicate glass over the at least one PMOS semiconducting fin and depositing a phosphosilicate glass over the at least one NMOS semiconducting fin.
